(19) United States
(12) Patent Application Publication
(10) Pub. No.: US 2021/0217792 A1
(43) Pub. Date: Jul. 15, 2021

(54) IMAGE SENSOR STRUCTURE AND MANUFACTURING METHOD THEREOF

(71) Applicant: Powerchip Semiconductor Manufacturing Corporation, Hsinchu (TW)

(72) Inventors: Chun-Liang Chen, Hsinchu County (TW); Chin-Te Huang, Hsinchu County (TW); Shih-Ping Lee, Hsinchu City (TW)

(73) Assignee: Powerchip Semiconductor Manufacturing Corporation, Hsinchu (TW)

(21) Appl. No.: 16/785,666

(22) Filed: Feb. 10, 2020

(30) Foreign Application Priority Data
Jan. 14, 2020 (TW) 109101139

(51) Int. Cl. H01L 27/146; H04N 9/04; H04N 5/225; G02B 5/20

(52) U.S. Cl. CPC H01L 27/14621; H04N 9/0455; H04N 5/2253; H01L 27/14685; G02B 5/208; H01L 27/14627; H01L 27/1464; H04N 5/2254

(57) ABSTRACT

An image sensor structure including a substrate, a light sensing device, a filter structure, and a separation wall is provided. The light sensing device is located in the substrate. The filter structure is located above the light sensing device. The filter structure includes a main filter layer and a first subordinate filter layer. The separation wall surrounds a sidewall of the filter structure. A refractive index of the filter structure is greater than a refractive index of the separation wall.

### CROSS-REFERENCE TO RELATED APPLICATION

This application claims the priority benefit of Taiwan application serial no. 109101139, filed on Jan. 14, 2020. The entirety of the above-mentioned patent application is hereby incorporated by reference herein and made a part of this specification.

### BACKGROUND OF THE INVENTION

### Field of the Invention

The invention relates to a semiconductor device and a manufacturing method thereof, and more particularly, to an image sensor structure and a manufacturing method thereof.

### Description of Related Art

An image sensing device manufactured by a semiconductor process may be used to sense light, such as a complementary metal oxide semiconductor (CMOS). The image sensing device uses a sensing unit array to receive light energy and convert it into digital data. However, how to improve the photoelectric conversion efficiency of the image sensor and prevent the occurrence of optical crosstalk in the image sensor are the objects of current industry efforts.

### SUMMARY OF THE INVENTION

The invention provides an image sensor structure and a manufacturing method thereof that may improve photoelectric conversion efficiency and prevent optical crosstalk.

The invention provides an image sensor structure including a substrate, a light sensing device, a filter structure, and a separation wall. The light sensing device is located in the substrate. The filter structure is located above the light sensing device. The filter structure includes a main filter layer and a first subordinate filter layer. The separation wall surrounds a sidewall of the filter structure. A refractive index of the filter structure is greater than a refractive index of the separation wall.

According to an embodiment of the invention, in the image sensor structure, the main filter layer may be a color filter layer.

According to an embodiment of the invention, in the image sensor structure, the filter structure may further include a second subordinate filter layer. The main filter layer, the first subordinate filter layer, and the second subordinate filter layer may be stacked on the substrate.

According to an embodiment of the invention, in the image sensor structure, the first subordinate filter layer may be one of an infrared (IR) cut filter and an ultraviolet (UV) cut filter. The second subordinate filter layer may be the other of the IR cut filter and the UV cut filter.

According to an embodiment of the invention, in the image sensor structure, a material of the separation wall is, for example, silicon oxide, silicon nitride, silicon oxynitride, a low-dielectric constant material, or a combination thereof.

According to an embodiment of the invention, in the image sensor structure, there may be a hole in the separation wall.

According to an embodiment of the invention, the image sensor structure may further include a separation structure. The separation structure is located in the substrate.

According to an embodiment of the invention, in the image sensor structure, the separation wall may be connected to the separation structure.

According to an embodiment of the invention, in the image sensor structure, a refractive index of the substrate may be greater than a refractive index of the separation structure.

According to an embodiment of the invention, in the image sensor structure, the separation structure may pass through the substrate.

According to an embodiment of the invention, the image sensor structure may further include an interface layer. The interface layer is located between the filter structure and the substrate.

According to an embodiment of the invention, the image sensor structure may further include a microlens layer. The microlens layer is located on the filter structure.

According to an embodiment of the invention, in the image sensor structure, the image sensor structure may be a backside illuminated (BSI) image sensor structure or a front-side illuminated (FSI) image sensor structure.

The invention provides a manufacturing method of an image sensor structure including the following steps. A light sensing device is formed in a substrate. A filter structure is formed above the light sensing device. The filter structure includes a main filter layer and a first subordinate filter layer. A separation wall surrounding a sidewall of the filter structure is formed. A refractive index of the filter structure is greater than a refractive index of the separation wall.

According to an embodiment of the invention, in the manufacturing method of the image sensor structure, a forming method of the filter structure may include the following steps. A filter structure layer is formed on the substrate. The filter structure layer includes a main filter material layer and a first subordinate filter material layer. A patterned mask layer is formed on the filter structure layer. A portion of the filter structure layer is removed using the patterned mask layer as a mask to form the filter structure and an opening surrounding the filter structure.

According to an embodiment of the invention, in the manufacturing method of the image sensor structure, the filter structure layer may further include a second subordinate filter material layer. The main filter material layer, the first subordinate filter material layer, and the second subordinate filter material layer may be stacked on the substrate.

According to an embodiment of the invention, in the manufacturing method of the image sensor structure, the separation wall may seal the opening.

According to an embodiment of the invention, in the manufacturing method of the image sensor structure, a forming method of the separation wall may include the following steps. A separation material layer is filled in the opening. The separation material layer located outside the opening is removed.

According to an embodiment of the invention, in the manufacturing method of the image sensor structure, there may be a separation structure in the substrate.

According to an embodiment of the invention, in the manufacturing method of the image sensor structure, the opening may expose the separation structure. The separation wall may be connected to the separation structure.

Based on the above, in the image sensor structure and the manufacturing method thereof provided by the invention, the separation wall surrounds the sidewall of the filter structure, and the refractive index of the filter structure is greater than the refractive index of the separation wall. In this way, when light enters the filter structure and is transmitted to the interface of the filter structure and the separation wall, light is totally reflected on this interface, thereby generating a light pipe effect. Since the above light pipe effect may increase the amount of light irradiated to the corresponding light sensing device, the photoelectric conversion efficiency of the image sensor may be improved. In addition, the light pipe effect may prevent light from being irradiated to other light sensing devices to prevent optical crosstalk.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are cross-sectional views of a manufacturing process of an image sensor structure of an embodiment of the invention.

FIG. 2 is a top view of the filter structure and the opening in FIG. 1C.

FIG. 3 is a top view of the filter structure and the separation wall in FIG. 1E.

FIG. 4 is a cross-sectional view of an image sensor structure of another embodiment of the invention.

### DESCRIPTION OF THE EMBODIMENTS

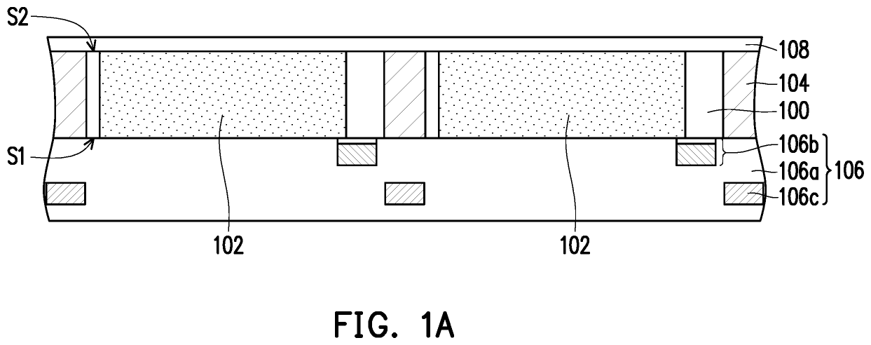

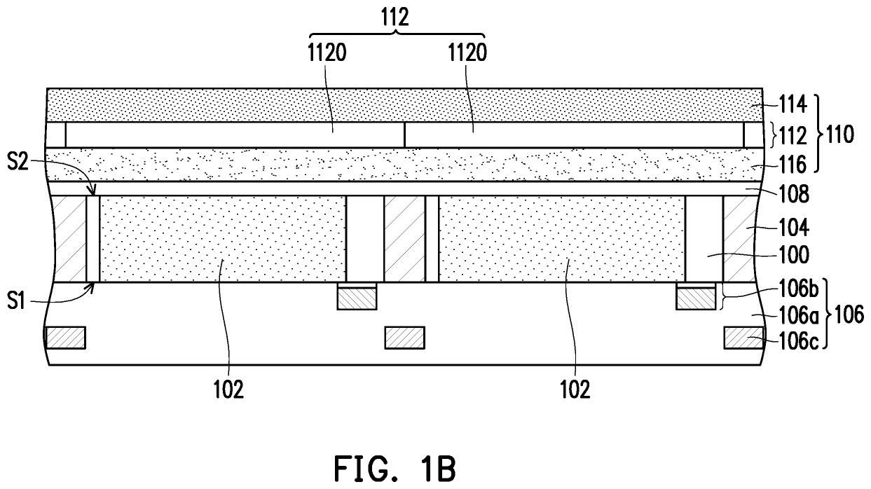

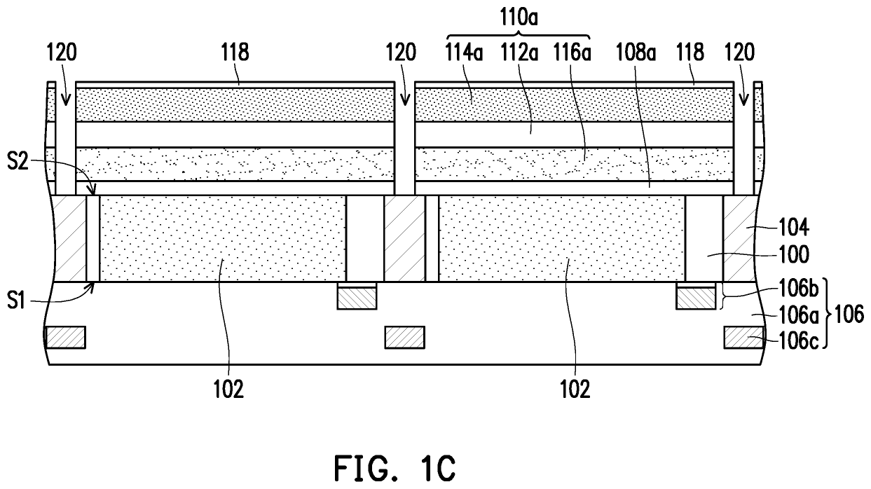

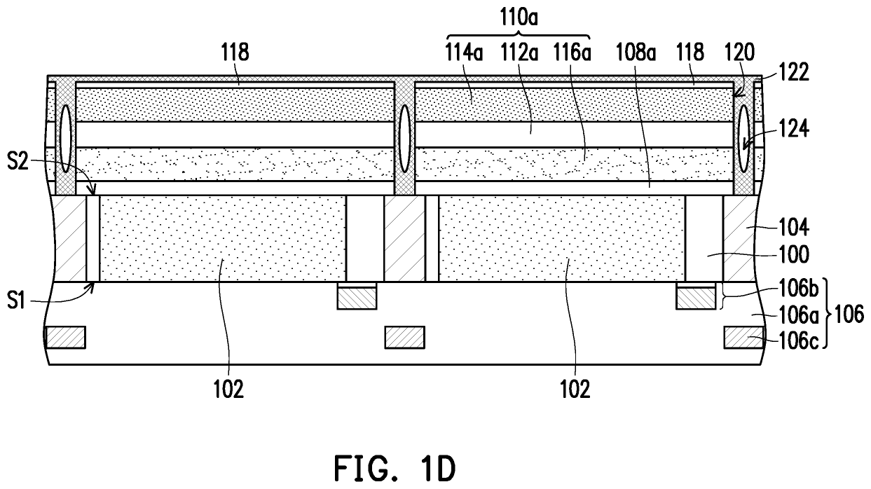

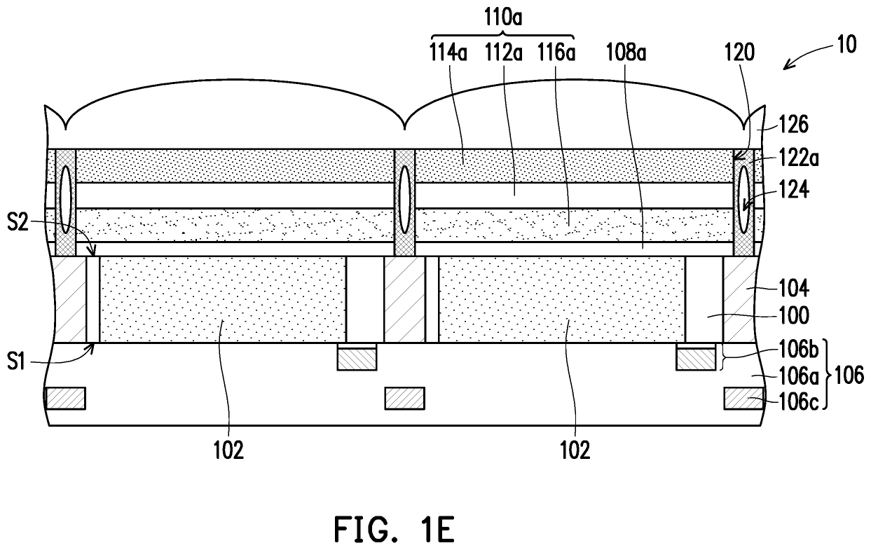

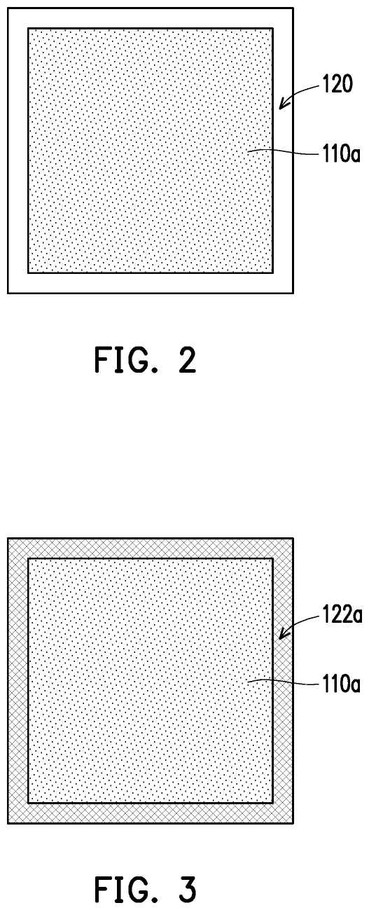

FIG. 1A to FIG. 1E are cross-sectional views of a manufacturing process of an image sensor structure of an embodiment of the invention. FIG. 2 is a top view of the filter structure and the opening in FIG. 1C. FIG. 3 is a top view of the filter structure and the separation wall in FIG. 1E. Some components in FIG. 1C and FIG. 1E are omitted in FIG. 2 and FIG. 3, respectively to clearly illustrate the arrangement relationship between the components in FIG. 2 and FIG. 3.

The image sensor structure may be a backside illuminated image sensor structure or a front-side illuminated image sensor structure. In the present embodiment, the image sensor structure is exemplified by a backside illuminated image sensor structure, but the invention is not limited thereto.

Referring to FIG. 1A, a light sensing device 102 is formed in a substrate 100. The substrate 100 is, for example, a semiconductor substrate such as a silicon substrate. The substrate 100 may have a first surface S1 and a second surface S2 opposite to each other. The first surface S1 may be one of a front surface and a back surface of the substrate 100, and the second surface S2 may be the other of the front surface and the back surface of the substrate 100. In the present embodiment, the first surface S1 is exemplified by the front surface of the substrate 100, and the second surface S2 is exemplified by the back surface of the substrate 100, but the invention is not limited thereto. The light sensing device 102 is, for example, a photodiode. A forming method of the light sensing device 102 is, for example, an ion implantation method.

In addition, there may be a separation structure 104 in the substrate 100. The refractive index of the substrate 100 may be greater than the refractive index of the separation structure 104. In this way, when light enters the substrate 100 and is transmitted to the interface of the substrate 100 and the separation structure 104, the light is totally reflected on this interface, thereby generating a light pipe effect. Since the light pipe effect may increase the amount of light irradiated to the corresponding light sensing device 102, the photoelectric conversion efficiency of the image sensor may be improved. In addition, the light pipe effect may prevent light from being irradiated to other light sensing devices 102 to prevent optical crosstalk. For example, when measuring with light having a wavelength of 633 nm, the refractive index of the substrate 100 may be about 3.8, and the refractive index of the separation structure 104 may be 1 to 3.

The separation structure 104 may be a deep trench isolation structure (DTI) or a combination of a DTI structure and a shallow trench isolation (STI) structure. The material of the separation structure 104 may include a dielectric material (e.g., silicon oxide). In some embodiments, a conductive material (such as a metal such as tungsten or doped polysilicon) (not shown) may be disposed inside the separation structure 104, and the separation structure 104 may be located between the conductive material and the substrate 100, so that the conductive material and the substrate 100 are separated. The separation structure 104 may pass through the substrate 100, but the invention is not limited thereto. In another embodiment, the separation structure 104 may not pass through the substrate 100.

In addition, the first surface S1 of the substrate 100 may have a circuit layer 106. The circuit layer 106 may include a dielectric layer 106a, a gate structure 106b, and an interconnect structure 106c, but the invention is not limited thereto. The gate structure 106b and the interconnect structure 106c are located in the dielectric layer 106a. In another embodiment, the gate structure 106b may be a recess gate structure located in the substrate 100.

Next, an interface material layer 108 may be formed on the second surface S2 of the substrate 100. The refractive index of the interface material layer 108 may be less than the refractive index of the substrate 100. The material of the interface material layer 108 is, for example, silicon oxide, silicon nitride, silicon oxynitride, titanium oxide (TiO2), or a high-dielectric constant light-transmitting material. The forming method of the dielectric material layer 108 is, for example, a chemical vapor deposition method.

Referring to FIG. 1B, a filter structure layer 110 is formed on the substrate 100. In the present embodiment, the filter structure layer 110 may be formed on the second surface S2 of the substrate 100. For example, the filter structure layer 110 may be formed on the interface material layer 108. The filter structure layer 110 may include a main filter material layer 112 and a subordinate filter material layer 114. In addition, the filter structure layer 110 may further include a subordinate filter material layer 116. The main filter material layer 112, the subordinate filter material layer 114, and the subordinate filter material layer 116 may respectively be used to filter light of a specific wavelength.

For example, the main filter material layer 112 may be a color filter material layer. The main filter material layer 112 may include at least one filter unit 1120. In the present embodiment, the main filter material layer 112 is exemplified by including a plurality of filter units 1120. The filter units 1120 may be one of a red filter unit, a green filter unit, or a blue filter unit, respectively. The material of the main filter material layer 112 is, for example, a photoresist material. The forming method of the main filter material layer 112 is known to those skilled in the art, and is not repeated herein.

Further, the subordinate filter material layer 114 may be one of an infrared cut filter material layer and a UV cut filter material layer, and the subordinate filter material layer 116 may be the other of the infrared cut filter material layer and the UV cut filter material layer. In the present embodiment, the subordinate filter material layer 114 is an infrared cut filter material layer as an example, and the subordinate filter material layer 116 is a UV cut filter material layer as an example, but the invention is not limited thereto. In another embodiment, the subordinate filter material layer 114 may be a UV cut filter material layer, and the subordinate filter material layer 116 may be an infrared cut filter material layer. The material of the infrared cut filter material layer is, for example, a photoresist material or a multilayer film capable of filtering infrared rays. The material of the UV cut filter material layer is, for example, a photoresist material or a multilayer film capable of filtering UV rays. The multilayer film may be formed by alternately stacking a high refractive index layer and a low refractive index layer. The forming method of the infrared cut filter material layer and the UV cut filter material layer is known to those skilled in the art, and is not repeated herein.

The main filter material layer 112, the subordinate filter material layer 114, and the subordinate filter material layer 116 may be stacked on the substrate 100 in any order. In the present embodiment, the subordinate filter material layer 116, the main filter material layer 112, and the subordinate filter material layer 114 are sequentially stacked on the substrate 100 as an example, that is, the subordinate filter material layer 116, the main filter material layer 112, and the subordinate filter material layer 114 may be sequentially formed on the substrate 100, but the invention is not limited thereto. In another embodiment, the filter structure layer 110 may not include the subordinate filter material layer 116. When the filter structure layer 110 does not include the subordinate filter material layer 116, the main filter material layer 112 and the subordinate filter material layer 114 may be stacked on the substrate 100 in any order.

Referring to FIG. 1C, a patterned mask layer 118 is formed on the filter structure layer 110. The material of the patterned mask layer 118 is, for example, a hard mask material such as silicon oxide, silicon nitride, or silicon oxynitride. The forming method of the patterned mask layer 118 is, for example, a combination of a deposition process, a lithography process, and an etching process. The deposition process is, for example, a chemical vapor deposition process, such as a plasma-enhanced chemical vapor deposition (PECVD) process.

Next, referring to FIG. 1C and FIG. 2, a portion of the filter structure layer 110 is removed using the patterned mask layer 118 as a mask to form a filter structure 110a and an opening 120 surrounding the filter structure 110a. Accordingly, the filter structure 110a is formed above the light sensing device 102. The removal method of the portion of the filter structure layer 110 is, for example, a dry etching method. In the present embodiment, although the forming method of the filter structure 110a is exemplified by the above method, the invention is not limited thereto.

In addition, the opening 120 may expose the separation structure 104. For example, during the process of forming the opening 120, a portion of the interface material layer 108 may also be removed to form an interface layer 108a and expose the separation structure 104. The top view of the opening 120 may be a ring, such as a square ring or a circular ring. In the present embodiment, as shown in FIG. 2, the top view shape of the opening 120 is exemplified by a square ring, but the invention is not limited thereto.

The filter structure 110a includes a main filter layer 112a and a subordinate filter layer 114a. In addition, the filter structure 110a may further include a subordinate filter layer 116a. The main filter layer 112a, the subordinate filter layer 114a, and the subordinate filter layer 116a may be stacked on the substrate 100 in any order. In the present embodiment, the subordinate filter layer 116a, the main filter layer 112a, and the subordinate filter layer 114a are sequentially stacked on the substrate 100 as an example, but the invention is not limited thereto. In another embodiment, the filter structure 110a may not include the subordinate filter layer 116a. When the filter structure 110a does not include the subordinate filter layer 116a, the main filter layer 112a and the subordinate filter layer 114a may be stacked on the substrate 100 in any order.

The main filter layer 112a may be a color filter layer. For example, the main filter layer 112a may be one of a red filter layer, a green filter layer, and a blue filter layer. The subordinate filter layer 114a may be one of an infrared cut filter and a UV cut filter. The subordinate filter layer 116a may be the other of the infrared cut filter and the UV cut filter. In the present embodiment, the subordinate filter layer 114a is exemplified by an infrared cut filter, and the subordinate filter layer 116a is exemplified by a UV cut filter. In another embodiment, the subordinate filter layer 114a may be a UV cut filter material layer, and the subordinate filter material layer 116a may be an infrared cut filter. The subordinate filter layer 114a and the subordinate filter layer 116a may respectively be used to improve signal-to-noise ratio (SNR).

Referring to FIG. 1D, a separation material layer 122 filled in the opening 120 is formed. The material of the separation material layer 122 is, for example, silicon oxide, silicon nitride, silicon oxynitride, a low-dielectric constant material, or a combination thereof. In addition, there may be a hole 124 in the separation material layer 122. The forming method of the separation material layer 122 is, for example, a CVD method, such as a PECVD method or a flowable chemical vapor deposition (FCVD) method.

Referring to FIG. 1E and FIG. 3, the separation material layer 122 located outside the opening 120 is removed to form a separation wall 122a surrounding the sidewall of the filter structure 110a. The removal method of the separation material layer 122 located outside the opening 120 is, for example, a chemical mechanical polishing method or an etch-back method.

The refractive index of the filter structure 110a is greater than a refractive index of the separation wall 122a. In the filter structure 110a, the refractive index of the main filter layer 112a, the refractive index of the subordinate filter layer 114a, and the refractive index of the subordinate filter layer 116a may be greater than the refractive index of the filter structure 110a, respectively, so that the overall refractive index of the filter structure 110a is greater than the refractive index of the separation wall 122a. In this way, when light enters the filter structure 110a and is transmitted to the interface of the filter structure 110a and the separation wall 122a, light is totally reflected at this interface, thereby generating a light pipe effect. Since the light pipe effect may increase the amount of light irradiated to the corresponding light sensing device 102, the photoelectric conversion efficiency of the image sensor may be improved. In addition, the light pipe effect may prevent light from being irradiated to other light sensing devices 102 to prevent optical crosstalk.

For example, when measuring with light having a wavelength of 633 nm, the refractive index of the main filter layer 112a, the refractive index of the subordinate filter layer 114a, and the refractive index of the subordinate filter layer 116a may be 1.4 to 1.8, and the refractive index of the separation wall 122a may be 1 to 1.45.

In the present embodiment, the hole 124 may be in the separation wall 122a, but the invention is not limited thereto. In the case that the hole 124 is in the separation wall 122a, since the hole 124 has air therein, the overall refractive index of the separation wall 122a may be between the refractive index of air and the refractive index of the material of the separation wall 122a. In another embodiment, the separation wall 122a may completely fill the opening 120 without having the hole 124. In an embodiment, the separation wall 122a may seal the opening 120 (FIG. 1E). In another embodiment, during the process of removing the separation material layer 122 located outside the opening 120, the hole 124 may also be exposed.

In addition, the top view shape of the separation wall 122a may be a ring, such as a square ring or a circular ring. In the present embodiment, as shown in FIG. 3, the top view shape of the separation wall 122a is exemplified by a square ring, but the invention is not limited thereto. In addition, the separation wall 122a may be connected to the separation structure 104, so that the separation wall 122a and the separation structure 104 may form a continuous structure, thereby producing a better light pipe effect.

In the present embodiment, although the forming method of the separation wall 122a is exemplified by the above method, the invention is not limited thereto. In another embodiment, the step of removing the separation material layer 122 located outside the opening 120 may be omitted, that is, the entire separation material layer 122 may be maintained, and the portion of the separation material layer 122 filled in the opening 120 may be used as the separation wall 122a.

In addition, the patterned mask layer 118 may be removed, but the invention is not limited thereto. The removal method of the patterned mask layer 118 is, for example, a chemical mechanical polishing method or an etch-back method. In another embodiment, the step of removing the patterned mask layer 118 may be omitted, i.e., the patterned mask layer 118 may be retained.

Next, a microlens layer 126 is formed on the filter structure 110a. The refractive index of the microlens layer 126 may be less than the refractive index of the filter structure 110a. For example, when the measurement is performed with light having a wavelength of 633 nm, the refractive index of the microlens layer 126 may be 1.4 to 1.8. The material of the microlens layer 126 is, for example, a photoresist material. The forming method of the microlens layer 126 is known to those skilled in the art, and is not repeated herein.

Hereinafter, the image sensor structure 10 of the present embodiment is described with reference to FIG. 1E. In addition, although the forming method of the image sensor structure 10 is exemplified by the above method as an example, the invention is not limited thereto.

Referring to FIG. 1E, the image sensor structure 10 includes the substrate 100, the light sensing device 102, the filter structure 110a, and the separation wall 122a. The light sensing device 102 is located in the substrate 100. The filter structure 110a is located above the light sensing device 102. The filter structure 110a includes the main filter layer 112a and the subordinate filter layer 114a, and may further include the subordinate filter layer 116a. The separation wall 122a surrounds a sidewall of the filter structure 110a. The refractive index of the filter structure 110a is greater than the refractive index of the separation wall 122a. In addition, the image sensor structure 10 may further include at least one of the separation structure 104, the circuit layer 106, the interface layer 108a, and the microlens layer 126. The separation structure 104 is located in the substrate 100. The circuit layer 106 is located on the first surface S1 of the substrate 100. The interface layer 108 a is located between the filter structure 110a and the substrate 100. The microlens layer 126 is located on the filter structure 110a. In addition, the materials, configuration methods, forming methods, and functions and the like of the components in the image sensor structure 10 are described in detail in the above embodiments, and are not repeated herein.

Based on the above embodiments, it may be known that, in the image sensor 10 and the manufacturing method thereof, the separation wall 122a surrounds the sidewall of the filter structure 110a, and the refractive index of the filter structure 110a is greater than the refractive index of the separation wall 122a. In this way, when light enters the filter structure 110a and is transmitted to the interface of the filter structure 110a and the separation wall 122a, light is totally reflected at this interface, thereby generating a light pipe effect. Since the light pipe effect may increase the amount of light irradiated to the light sensing device 102, the photoelectric conversion efficiency of the image sensor may be improved. In addition, the light pipe effect may prevent light from being irradiated to other light sensing devices 102 to prevent optical crosstalk.

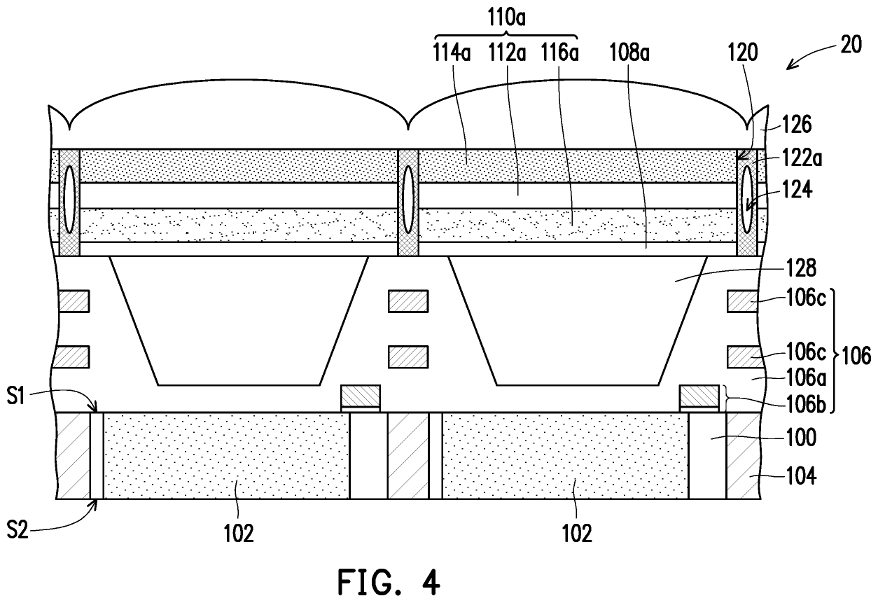

FIG. 4 is a cross-sectional view of an image sensor structure of another embodiment of the invention.

Please refer to FIG. 1E and FIG. 4. The differences between an image sensor structure 20 of FIG. 4 and the image sensor structure 10 of FIG. 1 are as follows. The image sensor structure 10 is a backside illuminated image sensor structure, and the image sensor structure 20 is a front-side illuminated image sensor structure. The interface layer 108a, the filter structure 110a, the separation wall 122a, and the microlens layer 126 of the image sensor structure 10 are located on the second surface S2 of the substrate 100, and the interface layer 108a, the filter structure 110a, the separation wall 122a, and the microlens layer 126 of the image sensor structure 20 are located on the first surface S1 of the substrate 100. For example, in the image sensor structure 20, the interface layer 108a, the filter structure 110a, and the microlens layer 126 may be sequentially disposed on the circuit layer 106, and the separation wall 122a surrounds the sidewall of the filter structure 110a. In addition, in the image sensor structure 20, the separation wall 122a is not connected to the separation structure 104. In the image sensor structure 20, a light pipe structure 128 may be optionally disposed in the dielectric layer 106a. In this way, the light pipe structure formed by the filter structure 110a and the separation wall 122a and the light pipe structure 128 underneath may be connected to each other, thereby further improving the light pipe effect. The material of the light pipe structure 128 is, for example, a light-transmitting material having a refractive index greater than the refractive index of an adjacent dielectric material. In addition, in the image sensor structure 20 and the image sensor structure 10, the same components are represented by the same reference numerals, and descriptions thereof are omitted.

Based on the above, in the image sensor structure and the manufacturing method thereof of the embodiments, since the separation wall surrounds the sidewall of the filter structure, and the refractive index of the filter structure is greater than the refractive index of the separation wall, a light tube effect may be generated, thereby improving the photoelectric conversion efficiency of the image sensor and preventing optical crosstalk.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. An image sensor structure, comprising:
a substrate;
a light sensing device located in the substrate;
a filter structure located above the light sensing device and comprising a main filter layer and a first subordinate filter layer; and
a separation wall surrounding a sidewall of the filter structure, wherein a refractive index of the filter structure is greater than a refractive index of the separation wall.

2. The image sensor structure of claim 1, wherein the main filter layer comprises a color filter layer.

3. The image sensor structure of claim 1, wherein the filter structure further comprises:
a second subordinate filter layer, wherein the main filter layer, the first subordinate filter layer, and the second subordinate filter layer are stacked on the substrate.

4. The image sensor structure of claim 3, wherein the first subordinate filter layer is one of an infrared cut filter and a UV cut filter, and the second subordinate filter layer is the other of the infrared cut filter and the UV cut filter.

5. The image sensor structure of claim 1, wherein a material of the separation wall comprises silicon oxide, silicon nitride, silicon oxynitride, a low-dielectric constant material, or a combination thereof.

6. The image sensor structure of claim 1, wherein there is a hole in the separation wall.

7. The image sensor structure of claim 1, further comprising:
a separation structure located in the substrate.

8. The image sensor structure of claim 7, wherein the separation wall is connected to the separation structure.

9. The image sensor structure of claim 7, wherein a refractive index of the substrate is greater than a refractive index of the separation structure.

10. The image sensor structure of claim 7, wherein the separation structure passes through the substrate.

11. The image sensor structure of claim 1, further comprising:
an interface layer located between the filter structure and the substrate.

12. The image sensor structure of claim 1, further comprising:
a microlens layer located on the filter structure.

13. The image sensor structure of claim 1, wherein the image sensor structure comprises a backside illuminated image sensor structure or a front-side illuminated image sensor structure.

14. A manufacturing method of an image sensor structure, comprising:
forming a light sensing device in a substrate;
forming a filter structure above the light sensing device, wherein the filter structure comprises a main filter layer and a first subordinate filter layer; and
forming a separation wall surrounding a sidewall of the filter structure, wherein a refractive index of the filter structure is greater than a refractive index of the separation wall.

15. The manufacturing method of the image sensor structure of claim 14, wherein a forming method of the filter structure comprises:
forming a filter structure layer on the substrate, wherein the filter structure layer comprises a main filter material layer and a first subordinate filter material layer;
forming a patterned mask layer on the filter structure layer; and
removing a portion of the filter structure layer using the patterned mask layer as a mask to form the filter structure and an opening surrounding the filter structure.

16. The manufacturing method of the image sensor structure of claim 15, wherein the filter structure layer further comprises:
a second subordinate filter material layer, wherein the main filter material layer, the first subordinate filter material layer, and the second subordinate filter material layer are stacked on the substrate.

17. The manufacturing method of the image sensor structure of claim 15, wherein the separation wall seals the opening.

18. The manufacturing method of the image sensor structure of claim 15, wherein a forming method of the separation wall comprises:
forming a separation material layer filled in the opening; and
removing the separation material layer located outside the opening.

19. The manufacturing method of the image sensor structure of claim 15, wherein there is a separation structure in the substrate.

20. The manufacturing method of the image sensor structure of claim 19, wherein the opening exposes the separation structure, and the separation wall is connected to the separation structure.
